(19) United States
(12) Patent Application Publication
(10) Pub. No.: US 2026/0341813 A1
(43) Pub. Date: Oct. 29, 2026

(54) METHODS AND SYSTEMS FOR SETTING UP BATTERY ASSEMBLY PROCESS OR EVALUATION EQUIPMENT

(71) Applicant: GM GLOBAL TECHNOLOGY OPERATIONS LLC, Detroit, MI (US)

(72) Inventors: Robert Benson Parrish, White Lake, MI (US); Jason A. Lupienski, Birmingham, MI (US); Andru O'Farrill, Washington, MI (US); Christopher Warmack, Goodrich, MI (US); Deepankar Thakur, Rochester, MI (US); Jonathan Estrada Nava, Fraser, MI (US)

(73) Assignee: GM GLOBAL TECHNOLOGY OPERATIONS LLC, Detroit, MI (US)

(21) Appl. No.: 19/187,909

(22) Filed: Apr. 23, 2025

(51) Int. Cl. H01M 10/42; G01M 1/12; G01R 31/389; H01M 10/48

(52) U.S. Cl. CPC H01M 10/4285; G01M 1/122; G01R 31/389; H01M 10/48

(57) ABSTRACT

A method is provided for preparing for processing of a production battery. The method includes determining a product exterior surface finish, product dimensions, product mass, and product center-of-gravity of the production battery; identifying a thermoplastic material and a surface grain for forming a housing having an exterior surface finish that is the same as the product exterior surface finish; modeling, with a processor, a surrogate battery including the housing and a ballast mass received within the housing, to provide the surrogate battery with a surrogate mass the same as the product mass and a surrogate center-of-gravity the same as the product center-of-gravity; forming the housing from the thermoplastic material and with the surface grain; forming the surrogate battery by positioning the ballast mass within the housing; and setting up equipment for processing the production battery by engaging the equipment with the surrogate battery.

### INTRODUCTION

The disclosure relates generally to battery module testing. More specifically, aspects of this disclosure relate to systems and methods for setting up equipment for assembling or testing battery modules.

Vehicles, including hybrid and hybrid-electric vehicles, include batteries for storage of electrical energy. The rechargeable battery or batteries may provide power used for vehicle traction. Furthermore, the batteries may be used to provide power for operation of accessories and for starting, lighting, and ignition functions of the vehicle.

A vehicle battery assembly may include a number of individual constituent battery cells arranged in a variety of suitable configurations. Thus, the battery assembly may include a number of internal electrical connections as well as external connections. It is important that connections are properly formed during manufacture and assembly of the battery assembly, thereby ensuring expected battery performance.

Equipment may be set up and dedicated to assembling and testing batteries. For example, testing may include evaluating the quality of electrical connections, evaluating weld junctions, measuring various cell voltages, evaluating the integrity of structural adhesive material (SAM), evaluating the integrity of thermal interface material (TIM), or evaluating other characteristics.

For new production, setting up such equipment may be delayed until a first product run of the battery is completed, so that the battery may be engaged by the equipment for testing. Yet having a way to test/prepare production processes without using actual production batteries would be advantageous.

Accordingly, there is a need for the ability to set up, modify, calibrate, or otherwise adjust equipment for testing production battery modules that avoids use of the production battery module. Furthermore, other desirable features and characteristics of the present disclosure will become apparent from the subsequent detailed description and the appended claims, taken in conjunction with the accompanying drawings and the foregoing technical field and background.

### SUMMARY

In one embodiment, a method is provided for preparing for processing of a production battery. The method includes determining a product exterior surface finish, product dimensions, product mass, and product center-of-gravity of the production battery; identifying a thermoplastic material and a surface grain for forming a housing having an exterior surface finish that is the same as the product exterior surface finish; modeling, with a processor, a surrogate battery including the housing and a ballast mass received within the housing, to provide the surrogate battery with a surrogate mass the same as the product mass and a surrogate center-of-gravity the same as the product center-of-gravity; forming the housing from the thermoplastic material and with the surface grain; forming the surrogate battery by positioning the ballast mass within the housing; and setting up equipment for processing the production battery by engaging the equipment with the surrogate battery.

In certain embodiments, the method further includes determining a product resistance of the production battery, wherein modeling the surrogate battery includes modeling the surrogate battery including the housing, the ballast mass, and an internal voltage source received within the housing, wherein the internal voltage source has a resistance that is the same as the product resistance, and wherein forming the surrogate battery includes positioning the ballast mass and the internal voltage source within the housing.

In certain embodiments of the method, modeling the surrogate battery includes modeling the surrogate battery including the housing, the ballast mass, the internal voltage source, an anode electrode and a cathode electrode received within the housing, wherein forming the surrogate battery includes positioning the ballast mass, the internal voltage source, the anode electrode and the cathode electrode within the housing.

In certain embodiments of the method, the anode electrode is a first anode electrode and the cathode electrode is a first cathode electrode, and wherein the method further includes: removing the first anode electrode and the first cathode electrode from the housing; and repeating the modeling, forming, and setting up operations using the housing with a second anode electrode and a second cathode electrode selected for a second battery.

In certain embodiments of the method, modeling the surrogate battery includes modeling the surrogate battery including the housing, the ballast mass, the internal voltage source, an anode electrode, and a cathode electrode received within the housing and attachment contacts, wherein forming the surrogate battery includes positioning the ballast mass, the internal voltage source, the anode electrode and the cathode electrode within the housing and mounting the attachment contacts onto the housing to form the surrogate battery.

In certain embodiments, the method further includes preparing a mold for the housing, wherein forming the housing from the thermoplastic material and with the surface grain includes molding the housing with the mold.

In certain embodiments of the method, forming the housing from the thermoplastic material and with the surface grain includes forming a first part and a second part of the housing, and the method further includes securing the first part to the second part after locating the internal voltage source and the ballast mass between the first part and the second part.

In certain embodiments of the method, modeling the surrogate battery includes modeling the surrogate battery including the housing, the ballast mass, the internal voltage source, an anode electrode, and a cathode electrode received within the housing and attachment contacts, wherein forming the surrogate battery includes positioning the ballast mass, the internal voltage source, the anode electrode and the cathode electrode within the housing and mounting the attachment contacts onto the housing to form the surrogate battery, wherein the attachment contacts are fastened to the housing and the first part is secured to the second part with fasteners, and wherein modeling the surrogate battery includes modeling the surrogate battery including the housing, the attachment contacts, the internal voltage source, the ballast mass, and the fasteners.

In certain embodiments, the method further includes determining a product bidirectional stiffness of the production battery, wherein modeling the surrogate battery includes modeling the surrogate battery to provide the surrogate battery with a bidirectional stiffness the same as the product bidirectional stiffness.

In another embodiment, a method for testing a production battery includes determining a product exterior surface finish, product dimensions, product mass, and product center-of-gravity of the production battery; identifying a thermoplastic material and a surface grain for forming a housing having an exterior surface finish that is the same as the product exterior surface finish; modeling, with a processor, a surrogate battery including the housing and a ballast mass received within the housing, to provide the surrogate battery with a surrogate mass the same as the product mass and a surrogate center-of-gravity the same as the product center-of-gravity; forming the housing from the thermoplastic material and with the surface grain; forming the surrogate battery by positioning the ballast mass within the housing; setting up equipment for processing the production battery by engaging the equipment with the surrogate battery; and removing the surrogate battery from the equipment; engaging the production battery with the equipment; and performing testing on the production battery.

In certain embodiments, the method further includes determining a product resistance of the production battery, wherein modeling the surrogate battery includes modeling the surrogate battery including the housing, the ballast mass, and an internal voltage source received within the housing, wherein the internal voltage source has a resistance that is the same as the product resistance, and wherein forming the surrogate battery includes positioning the ballast mass and the internal voltage source within the housing.

In certain embodiments of the method, modeling the surrogate battery includes modeling the surrogate battery including the housing, the ballast mass, the internal voltage source, an anode electrode and a cathode electrode received within the housing, wherein forming the surrogate battery includes positioning the ballast mass, the internal voltage source, the anode electrode and the cathode electrode within the housing.

In certain embodiments of the method, the anode electrode is a first anode electrode and the cathode electrode is a first cathode electrode, and the method further includes removing the first anode electrode and the first cathode electrode from the housing; and repeating the modeling, forming, and setting up operations using the housing with a second anode electrode and a second cathode electrode selected for a second battery.

In certain embodiments of the method, modeling the surrogate battery includes modeling the surrogate battery including the housing, the ballast mass, the internal voltage source, an anode electrode, and a cathode electrode received within the housing and attachment contacts, wherein forming the surrogate battery includes positioning the ballast mass, the internal voltage source, the anode electrode and the cathode electrode within the housing and mounting the attachment contacts onto the housing to form the surrogate battery.

In certain embodiments, the method further includes preparing a mold for the housing, wherein forming the housing from the thermoplastic material and with the surface grain includes molding the housing with the mold.

In certain embodiments of the method, forming the housing from the thermoplastic material and with the surface grain includes forming a first part and a second part of the housing, and the method further includes securing the first part to the second part after locating the internal voltage source and the ballast mass between the first part and the second part.

In certain embodiments of the method, modeling the surrogate battery includes modeling the surrogate battery including the housing, the ballast mass, the internal voltage source, an anode electrode, and a cathode electrode received within the housing and attachment contacts, forming the surrogate battery includes positioning the ballast mass, the internal voltage source, the anode electrode and the cathode electrode within the housing and mounting the attachment contacts onto the housing to form the surrogate battery, the attachment contacts are fastened to the housing and the first part is secured to the second part with fasteners, and modeling the surrogate battery includes modeling the surrogate battery including the housing, the attachment contacts, the internal voltage source, the ballast mass, and the fasteners.

In certain embodiments of the method, performing testing on the production battery includes checking structural adhesive material (SAM).

In certain embodiments of the method, performing testing on the production battery includes checking thermal interface material (TIM).

In another embodiment, a system for processing a production battery is provided and includes a processor configured to: identify a material and a surface grain for forming a housing having an exterior surface finish that is the same as a product exterior surface finish of the production battery; and model a surrogate battery including the housing and a ballast mass received within the housing, to provide the surrogate battery with a surrogate mass the same as a product mass of the production battery and a surrogate center-of-gravity the same as a product center-of-gravity of the production battery; a mold for forming the housing; the ballast mass; and equipment for processing the production battery, wherein the equipment is configured to engage the surrogate battery during a set up operation.

### DESCRIPTION OF THE DRAWINGS

The present disclosure will hereinafter be described in conjunction with the following drawing figures, wherein like numerals denote like elements, and wherein:

FIG. 1 is a schematic perspective view of a portion of a battery module for a battery assembly for use in accordance with the embodiments of the disclosure;

FIG. 2 is a schematic isometric view of a portion of a multi-cell battery of the battery assembly in accordance with the disclosure;

FIG. 3A is a schematic side view of a portion of a battery cell similar to that shown in FIG. 2 having a single-tab configuration;

FIG. 3B is a schematic side view of a portion of a battery cell similar to that shown in FIG. 2 having a three-tab configuration;

FIG. 4 is a schematic perspective view of a battery testing unit for use with the battery assembly in accordance with embodiments of the disclosure;

FIG. 5 is a schematic perspective view of a portion of a lower surface of the battery testing unit housing of the battery testing unit;

FIG. 6 is a schematic side sectional view of the battery testing unit in accordance with the disclosure;

FIG. 7 is another schematic side sectional view of the battery testing unit;

FIG. 8 is a schematic perspective view of a battery unit of the battery assembly;

FIG. 9 is a schematic perspective view of the battery testing unit disposed adjacent the battery unit for evaluating battery connection quality;

FIG. 10 is a schematic view of a battery connection quality system for use in accordance with the embodiments of the disclosure; and

FIG. 11 is a schematic view of an exemplary system for implementing the system for evaluating battery connection quality in accordance with the embodiments of the disclosure.

FIG. 12 is a schematic view of a production battery cell in accordance with the embodiments of the disclosure.

FIG. 13 is an exploded view of a surrogate battery cell in accordance with the embodiments of the disclosure.

FIG. 14 is an internal view of the surrogate battery cell of FIG. 13 in accordance with the embodiments of the disclosure.

FIG. 15 is an exploded perspective view illustrating a stack of surrogate units in accordance with the embodiments of the disclosure.

FIG. 16 is a flow chart illustrating a method for testing a battery production unit 210.

### DETAILED DESCRIPTION

Embodiments of the present disclosure may be described herein in terms of functional and/or logical block components and various processing steps. It should be appreciated that such block components may be realized by any number of hardware, software, and/or firmware components configured to perform the specified functions. For example, an embodiment of the present disclosure may employ various integrated circuit components, e.g., memory elements, digital signal processing elements, logic elements, look-up tables, or the like, which may carry out a variety of functions under the control of one or more microprocessors or other control devices. In addition, those skilled in the art 0will appreciate that embodiments of the present disclosure may be practiced in conjunction with any number of automated driving systems including cruise control systems, automated driver assistance systems and autonomous driving systems, and that the vehicle system described herein is merely one example embodiment of the present disclosure.

For the sake of brevity, conventional techniques and components related to vehicle mechanical parts and other functional aspects of the system (and the individual operating components of the system) may not be described in detail herein. Furthermore, the connecting lines shown in the various figures contained herein are intended to represent example functional relationships and/or physical couplings between the various elements. It should be noted that many alternative or additional functional relationships or physical connections may be present in an embodiment. It should also be understood that the figures are merely illustrative and may not be drawn to scale.

Additionally, the following description refers to elements or features being “connected” or “coupled” together. As used herein, “connected” may refer to one element/feature being directly joined to (or directly communicating with) another element/feature, and not necessarily mechanically. Likewise, “coupled” may refer to one element/feature being directly or indirectly joined to (or directly or indirectly communicating with) another element/feature, and not necessarily mechanically. However, it should be understood that, although two elements may be described below, in one embodiment, as being “connected,” in alternative embodiments similar elements may be “coupled,” and vice versa. Thus, although the schematic diagrams shown herein depict example arrangements of elements, additional intervening elements, devices, features, or components may be present in an actual embodiment.

For purposes of the present description, unless specifically disclaimed, use of the singular includes the plural and vice versa, the terms “and” and “or” shall be both conjunctive and disjunctive, and the words “including”, “containing”, “comprising”, “having”, and the like shall mean “including without limitation”. Moreover, words of approximation such as “about”, “almost”, “substantially”, “generally”, “approximately”, etc., may be used herein in the sense of “at, near, or nearly at”, or “within 0-5% of”, or “within acceptable manufacturing tolerances”, or logical combinations thereof. As used herein, a component that is “configured to” perform a specified function is capable of performing the specified function without alteration, rather than merely having potential to perform the specified function after further modification. In other words, the described hardware, when expressly configured to perform the specified function, is specifically selected, created, implemented, utilized, programmed, and/or designed for the purpose of performing the specified function.

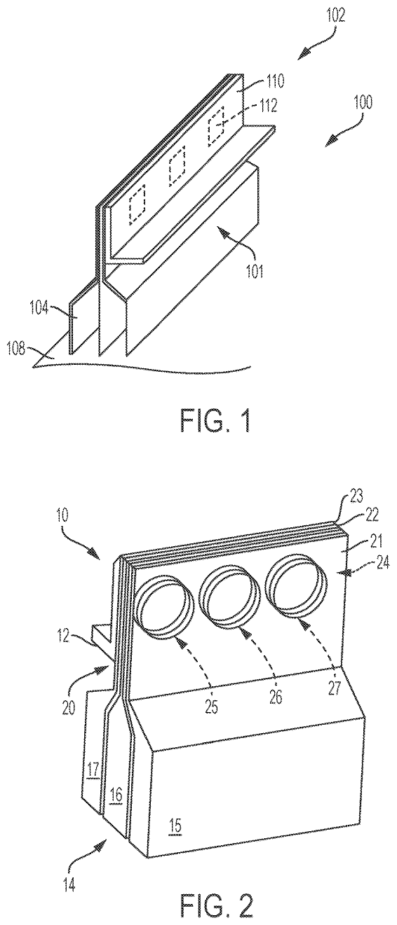

Referring to the drawings, wherein like reference numbers correspond to like or similar components throughout the several Figures, FIG. 1, consistent with embodiments disclosed herein, illustrates a portion of a battery module 101 of a battery assembly 100, such as a battery assembly included in a motor vehicle (not shown). The vehicle may include, but not be limited to, a commercial vehicle, industrial vehicle, passenger vehicle, aircraft, watercraft, train or the like. It is also contemplated that the vehicle may be a mobile platform, such as an airplane, all-terrain vehicle (ATV), boat, personal movement apparatus, robot and the like to accomplish the purposes of this disclosure.

The battery assembly 100 may include a plurality of individual constituent battery cells. The battery assembly 100 or constituent cells may be configured to provide an amount of electric power sufficient to operate a variety of systems associated with a vehicle including, for example, vehicle drivetrain systems. The battery cells may utilize battery technology that may include, for example, lead-acid, nickel-metal hydride (NiMH), lithium-ion (Li-Ion), Li-Ion polymer, lithium-air, nickel-cadmium (NiCad), valve-regulated lead-acid (VRLA) including absorbed glass mat (AGM), nickel-zinc (NiZn), molten salt (ZEBRA battery), nickel manganese cobalt (NMC), lithium iron phosphate (LFP), lithium manganese oxide (LMO), as well as other suitable battery technologies and/or combinations thereof.

Individual battery cells may be electrically connected to form a battery cell group. In certain embodiments, a plurality of battery cell groups may be incorporated in a battery module 101. A plurality of battery modules 101 may be similarly included in one or more battery units of a battery assembly 100. In certain embodiments, individual battery cells included in a battery assembly 100 may include prismatic, pouch, blade, or cylindrical cells. Individual battery cells may be arranged in a stack configuration, and may include tabs 104 forming battery cell terminals that may be suitably electrically connected for provision of electrical power to loads and/or for charging and/or discharging of the battery cells.

In some embodiments, a plurality of individual battery cells may be electrically connected in parallel via associated tabs to form a battery cell group. A plurality of battery cell groups may be electrically connected in series via one or more common buses or interconnecting members 102, such as L-shaped channels, to form a battery module included in a battery pack.

FIG. 1 shows a perspective view of a non-limiting example of a portion of a multi-cell battery assembly 100 for a vehicle (not shown) having an elongated L-shaped interconnecting member 102. A battery module 101 may include an extended series of interconnecting members 102 arranged side-by-side in multiple rows.

Each interconnecting member 102 joins oppositely charged battery cell tabs 104 of adjacent battery cells, with the battery cell tabs 104 forming individual electrode extensions of a given battery cell. Each battery cell tab 104 may be internally-welded below an interconnecting board 108 to the various anodes or cathodes of that particular battery cell, as is well understood by those of ordinary skill in the art. The battery cell tabs 104 may be welded to a longitudinal side wall 110 of a given interconnecting member 102, with substantially identical welds 112 formed at each interconnecting member 102.

Referring now to FIG. 2, an isometric view of a portion of a multi-cell battery module 10 of the battery assembly is shown that is consistent with embodiments disclosed herein. In certain embodiments, the multi-cell battery module 10 may be included in a battery assembly configured to power systems associated with a vehicle (not shown). The battery module 10 includes a plurality of joints between components. Each of the joints includes a plurality of first members or first sides, such as at least one interconnecting member 12 and a plurality of second members or second sides, such as battery cells 14. The first and second members are on opposing sides of the joint, and designation as first or second is not limiting. The battery cells 14 may be individually denoted as a first cell 15, a second cell 16, and a third cell 17. However, it is understood that the battery cells 14 may be assembled with a first cell 15 and a second cell 16. The two battery cell and three battery cell configurations will be collectively described. Features and components shown in other figures may be incorporated and used with those shown in FIG. 1.

The interconnecting member 12 shown may be referred to as a common bus or an L-shaped channel bus. The battery module 10, or portions thereof, may alternatively be referred to as a battery pack. Furthermore, each of the first through third cells 15, 16, 17 may be configured to operate as individual batteries, which are then combined and arranged to provide specific characteristics for the battery module 10, as required by the specific hybrid or hybrid-electric vehicles into which the battery module 10 may be incorporated. The battery cells 15, 16, 17 may utilize battery technology and/or chemistries as described above individually or in combination.

As described herein, the attachments for the interconnecting member 12 are shown, and the interconnecting member 12 may be in communication with fewer or more battery cells 14 than shown. The exact configurations of the portion of the battery module 10 shown in the Figures are illustrative and do not limit the scope of the disclosure. The interconnecting member 12 may be common to one or more battery cells 14 and may be formed of a non-conductive material. It is understood that the interconnecting member 12 may also include electrically conductive material including, without limitation, copper, aluminum, or the like. The interconnecting member 12 may be configured to connect a battery cell group in series with adjacent cell groups included in the battery assembly.

The battery cells 14 are attached to the interconnecting member 12 through a plurality of tabs 20, which may be disposed on the second members of the joints. The first, second, and third cells 15, 16, and 17, include a first tab 21, a second tab 22, and a third tab 23, respectively. Each of the battery cells 14 and tabs 20 may be substantially identical, such that an individual battery cell 14 may be designated as first, second, or third.

Electrical connection between the tabs 20 occurs through a plurality of weld joints 24. The weld joints 24 are composite joints formed from the individual weld nugget joints. Specific weld joints 24 may be referred to as a first weld stack 25, a second weld stack 26, and a third weld stack 27. More or fewer weld joints 24 may be used to electrically connect the tabs 20.

In certain embodiments, battery cell tabs 20 may be electrically connected via one or more welds, solder connections, mechanical connectors, or electrically conductive adhesives. For example, battery cell tabs 20 may be electrically connected via one or more ultrasonic welds, laser welds, ion-beam welds, resistance welds, friction welds, or the like. In other embodiments, battery cell tabs 20 and the associated interconnecting member 12 may be electrically connected via conductive rivets, clips, clamps, or the like.

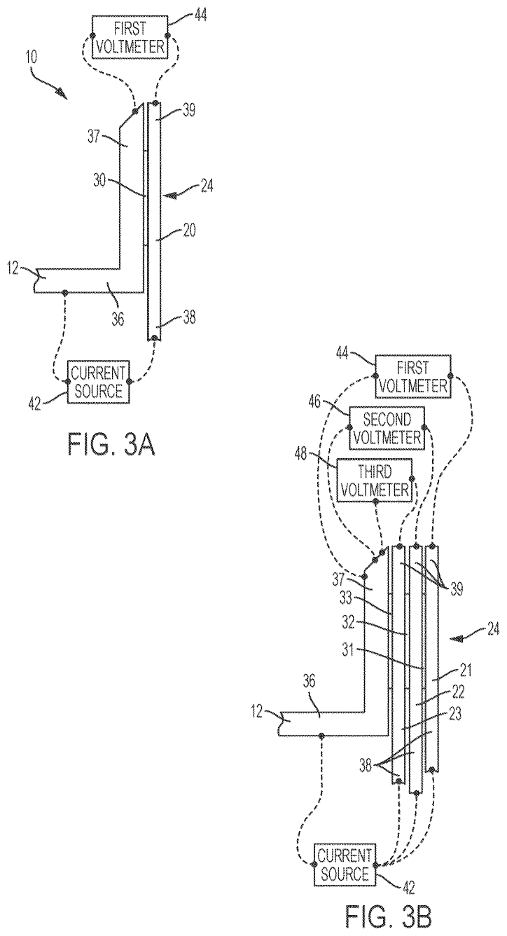

Referring now to FIG. 3A and FIG. 3B, and with continued reference to FIG. 2, there are shown two side views of portions of battery modules 10 similar to the portion of the battery module 10 shown in FIG. 2. FIG. 3A shows a side view of a single-tab configuration in which the tab 20 is welded directly to the interconnecting member 12, such that the weld joint 24 includes one weld nugget 30. FIG. 3B shows a side view of a two-tab or three-tab configuration in which the two or three tabs 20 are welded to the interconnecting member 12, such that the weld joint 24 has three weld nuggets 30, a first weld nugget 31, a second weld nugget 32, and a third weld nugget 33. Features and components shown in other Figures may be incorporated and used with those shown in FIGS. 3A and 3B.

Although illustrated as separately-identifiable components, the weld nuggets 30 may generally be considered as zones of coalescence between the adjacent tabs 20. Furthermore, adjacent tabs 20 may be pressed together during assembly, such that a side-view would not necessarily show the individual weld nuggets 30 between the tabs 20. The weld nuggets 30 may be of varying thickness and area and may be formed by resistance welding, ultrasonic welding, or other suitable welding processes. The weld nuggets 30, individually, or the weld joints 24 may also be referred to as joints or weld joints. The weld nuggets 30 may be individually measured or checked for joint integrity or the weld joints 24 may be measured for overall joint integrity.

As shown in FIG. 3A, the L-shaped interconnecting member 12 has a first end 36 and a second end 37, which are disposed on opposing sides of the weld nugget 30. Similarly, the tab 20 has a first end 38 and a second end 39, which are also disposed on opposing sides of the weld nugget 30. The first end 36 of the interconnecting member 12 and the first end 38 of the tab 20 are on the same relative side of the weld nugget 30. The location of the weld nugget 30, or the other joint types, defines the relative location of the first ends 36, 38 and the second ends 37, 39. Therefore, the first ends 36, 38, as viewed in the Figures are below the joint and the second ends 37, 39, as viewed in the Figures, are above the joint.

The battery evaluating or testing system consistent with embodiments disclosed herein may be used in connection with determining a quality of electrical connections between battery cell tabs and/or associated common busses, between interconnecting members, and/or between battery cell sense line in the U-channel and a fused trace line connected to the interconnected board (ICB) connected together via a rivet, fastener or the like as will be described in greater detail below. In some embodiments, the disclosed may further be used in connection with identifying improperly formed, acceptable, and/or unacceptable electrical connections between battery cell tabs and/or associated interconnecting members. In certain embodiments, a quality of a welded battery cell tab electrical connection may be determined based on a supplied current and a measured resistance across the electrical connection. In further embodiments, a quality of a welded battery cell tab electrical connection may be determined based on measuring a voltage drop across a cell group of a multi-cell battery assembly, thereby providing an indication of whether a desired number of battery cells in the cell group are electrically connected via the welded battery cell tab electrical connection.

In one of the embodiments of the disclosure, the battery cell 14 or the tab 20 is connected to a current source 42, which supplies a current to the first end 38 of the tab 20 via wires or conductors, shown as dashed lines such that current moves through the weld nugget 30. The current source 42 may include a voltage source and a precision resistor. Therefore, the current source 42 may also supply a voltage at a controlled resistance to the first end 38 of the tabs 20. A first voltmeter 44 measures a voltage differential at the second end 39 of the tabs 20.

From the current and the measured voltage, it is possible to calculate the resistance of the weld nugget 30. The calculated resistance may be indicative of the quality of the weld connection or nugget 30. For example, if the weld nugget 30 does not include continuous coalescence between the tabs 20 flow of the current from the tabs 20 may be impeded, causing the calculated resistance to increase. Furthermore, if the weld nugget 30 is broken or has significant cracking, the calculated resistance may also increase greatly.

The three-tab configuration shown in FIG. 3B may be the same configuration of the battery module 10 as is shown in FIG. 2. It is also understood that a two-tab configuration may be used for the battery module 10. The weld joint 24 shown in FIG. 3B includes the first weld nugget 31, the second weld nugget 32, and the third weld nugget 33. The weld joint 24 may be one or more of the first weld stack 25, the second weld stack 26, and the third weld stack 27 shown in FIG. 2.

The first tab 21 has a first end 38 and a second end 39, which are disposed on opposing sides of the first weld nugget 31. The first end 36 of the interconnecting member 12 and the first end 38 of the first tab 21 are on the same relative side of the first weld nugget 31. Similarly, the second tab 22 has a first end 38 and a second end 39 disposed on opposing sides of the second weld nugget 32, and the third tab 23 has a first end 38 and a second end 39 disposed on opposing sides of the third weld nugget 33.

The current source 42 is connected to the first ends 38 of the first tab 21, the second tab 22, and the third tab 23. A first current (I₁) is supplied by the current source 42 between the first end 36 of the interconnecting member 12 and the first end 38 of the first tab 21. Similarly, a second current (1₂) is supplied by the current source 42 between the first end 36 of the interconnecting member 12 and the first end 38 of the second tab 22, and a third current (1₃) is supplied by the current source 42 between the first end 36 of the interconnecting member 12 and the first end 38 of the third tab 23. The first current, the second current, and the third current may be substantially equal, such that each is approximately one-third of a total stack current (I) supplied by the current source 42.

I₁=I₂=I₃=I/3

The first voltmeter 44 measures a first voltage (V₁) between the second end 37 of the interconnecting member 12 and the second end 39 of the first tab 21. A second voltmeter 46 is attached to the second end 37 of the interconnecting member 12 and the second end 39 of the second tab 22, and measures a second voltage (V₂) therebetween. A third voltmeter 48 is attached to the second end 37 of the interconnecting member 12 and the second end 39 of the third tab 23, and measures a third voltage (V₃) therebetween.

Electrical current in metallic conductors is realized through a flow of electrons. Ohm's law states that the current through a conductor between two points is directly proportional to the potential difference across the two points. The coefficient of proportionality is an inverse of the resistance between the two points. The current in metallic conductors usually obeys Ohm's law. Therefore, the ratio of the voltage to current applied to a metallic conductor or set of conductors, caused by this voltage, is constant and may be called the effective resistance of the set of conductors to the voltage or current applied.

From the total stack current and from the measured first, second, and third voltages, the resistance of each of the first, second, and third weld nuggets 31, 32, 33 may be calculated. A first nugget resistance (R₁₂) is the resistance of the first weld nugget 31 between the first tab 21 and the second tab 22. A second nugget resistance (R₂₃) is the resistance of the second weld nugget 32 between the second tab 22 and the third tab 23. A third nugget resistance (R_{3b}) is the resistance of the third weld nugget 33 between the third tab 23 and the interconnecting member 12. The first, second, and third nugget resistances 31, 32, 33 may be determined or calculated as three unknowns in three equations.

V₁=I*(⅓*R₁₂+⅔*R₂₃+R_{3b})

V₂=I*(⅔*R₂₃+R_{3b})

V₃=I*(R_{3b})

The individual resistances of each of the first weld nugget 31, the second weld nugget 32, and the third weld nugget 33 may be compared to weld quality range having a predetermined minimum nugget resistance and a predetermined maximum nugget resistance. The results of the comparison may then be output to a receiver (not shown, which may be, for example and without limitation: a computer logging data, an operator testing the battery module 10 or portions thereof, or an automated testing and sorting process. The specific values of the weld quality range may vary greatly based upon the type of battery module 10, the materials used for the tabs 20, and the type of welding process used to create the weld nuggets 30 and the weld joints 24.

The results of the comparisons may include, for example and without limitation: a measurement error, a failed joint, and an acceptable joint. When the measured joint is a welded joint, the results of the comparisons may include, for example and without limitation: a measurement error, a failed weld, and an acceptable weld. The measurement error result may be output if the calculated first resistance is below the predetermined minimum nugget resistance. While low resistance generally indicates a better-quality weld, it may be assumed that below the predetermined minimum resistance there is a testing error because even welds of the best quality cannot reduce resistance below, for example, the resistance of the solid materials used.

The failed weld result may be output if the calculated first resistance is above the predetermined maximum nugget resistance, indicating that the weld quality is low and current is having difficulty flowing through the weld joint 24. The acceptable weld result may be output if the calculated first resistance is above the predetermined minimum nugget resistance and below the predetermined maximum nugget resistance such that the resistance falls within the weld quality range.

Comparison of the individual resistances may identify quality compliance issues in manufacturing or assembly of the battery module 10. For example, and without limitation, after several tests and comparisons, it may be determined that the third weld nugget 33 is often not fully-formed, and the welding process may be adjusted accordingly.

In addition to solving the three equations for the resistance of each of the individual nuggets, the parenthetical quantities may be determined as resistance constants for portions of the weld joint 24. A first weld stack resistance (R1) is the total resistance of the weld joint 24, and may be indicative of the total quality of the weld joint 24 as a whole. The resistance constant for the weld joint 24 is not the resistance of a specific element, but is the total effective resistance between the first tab 21 and the interconnecting member 12.

V₁=I*(R₁)

A weld quality range may also be applied to the resistance constant for the whole weld joint 24, such that the first weld stack resistance is compared to a predetermined minimum stack resistance and a predetermined maximum stack resistance. The individual resistances of the first, second, and third weld nuggets 31, 32, 33 may help identify specific manufacturing flaws. The resistance constant for the whole weld joint 24, however, may help identify successful assembly of that portion of the battery module 10 for quality control. It may be that each of the weld joints 24 needs to function for the battery module 10 to clear inspection. In such a case, it may be irrelevant which of the weld nuggets 30 within the weld joint 24 has defaults.

The weld joint 24 may be the first weld stack 25 shown in FIG. 2. Similarly, referring to FIG. 2, each of the first weld stack 25, the second weld stack 26, and the third weld stack 27 may have the total current supplied between the first end 38 of the first tab 21 and the first end 36 of the interconnecting member 12. One voltmeter may be connected above each of the first through third weld stacks 25-27, similar to the first voltmeter 44 shown in FIG. 3B, to the second end 39 of the first tab 21 and the second end 37 of the interconnecting member 12.

From the total current supplied below each of the first through third weld stacks 25-27 and from the voltage measured above each of the first through third weld stacks 25-27, the resistance constant may be determined for each of the first through third weld stacks 25-27. Furthermore, the resistance constants of each of the first through third weld stacks 25-27 may be compared to the weld quality range to determine whether the total stack weld quality is within the predetermined range. Because the first through third weld stacks 25-27 represent easier paths for current flow than directly between the un-welded portions of the tabs 20, the tabs 20 may be treated as if they are electrically separate, or have air gaps, between the first through third weld stacks 25-27 when determining the resistance thereof.

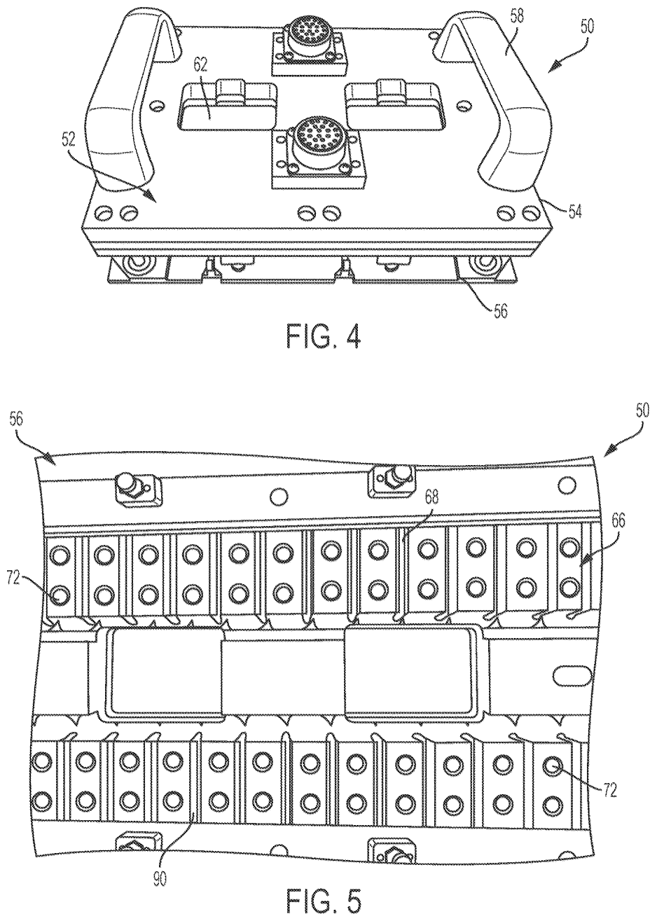

Referring now to FIGS. 4-10, a battery testing unit, generally referenced by numeral 50 for use with the battery testing system of the disclosure is illustrated and described. FIGS. 4-7 illustrate the battery testing unit 50 having a housing 52 with an upper surface 54 and an opposing lower surface 56. One or more handles 58 may be disposed on the upper surface 54 of housing 52 to allow for manual or automated placement of the battery testing unit 50 adjacent the battery unit 60. The battery testing unit 50 may be engaged and positioned by human interaction or through the use of a controlled or automated machine.

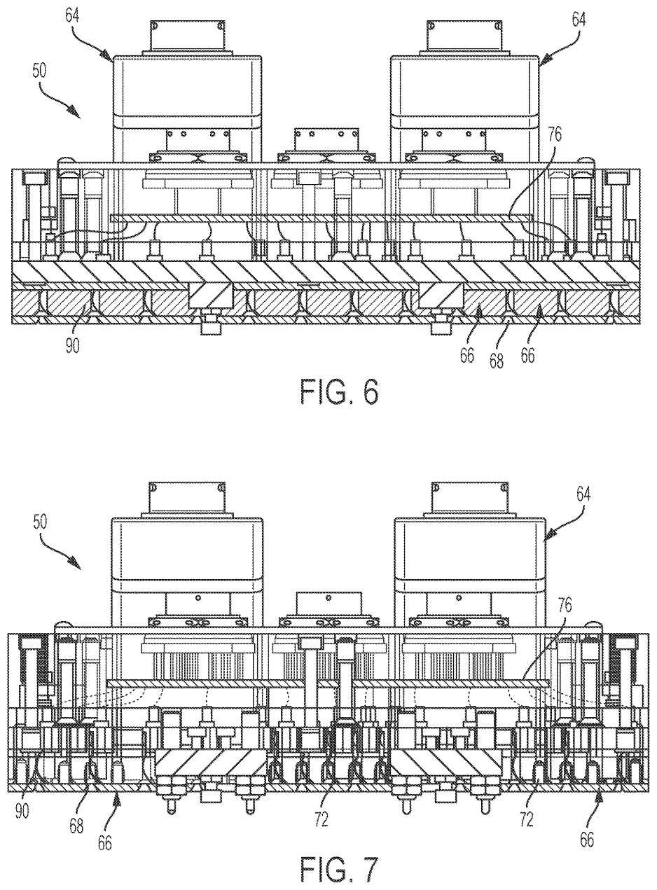

The housing 52 further includes one or more apertures 62 extending at least partially through the housing 52 to removably secure at least one external connector 64 therein. The at least one external connector 64, as is best shown in FIGS. 6 and 7, extends through the aperture 62 in housing 52 to provide a resistance connection point for at least one or both of the tab and/or associated interconnecting member of a battery module of the battery assembly. The at least one external connector 64 includes one or more leads or connections that electrically communicate with the plurality of testing modules 66 to reduce complexity of the battery testing unit 50. It is contemplated that the at least one external connector 64 may be used in the battery testing unit housing 52 or may be manually applied through the battery testing unit 50 to accomplish the objectives of the disclosure.

Referring now to FIGS. 5-7, a plurality of testing modules 66 are configured to communicate with and electrically contact opposing sides of tabs of the battery tabs and associated interconnecting member (ICB) of the battery module. Testing modules 66 may be positioned in a variety of locations and alignments to correspond with the configuration of the battery packs of the battery module in the battery assembly. The plurality of testing modules 66 each include a body that is disposed adjacent a lower surface 56 of the housing 52 and are spaced apart from the bodies of adjacent testing modules 66. In one embodiment of the disclosure, the body of testing module 66 includes a lower surface receiving at least one element 72 and one or more side surfaces extending from the lower surface to receive and support at least one contact 90 thereon as will be described in greater detail below. The bodies of adjacent testing modules 66 define a slot or channel 68 therebetween.

It is contemplated that channel 68 may be sized to receive the welded combination of the interconnecting member and tabs of a battery pack therein and bring the member and tabs in communication with at least one contact 90. Further, the positioning of the plurality of testing modules 66 and corresponding channels 68 may allow closer tab to tab spacing of the battery packs, thereby allowing for increased battery unit energy density. The leads or connections of the at least one external connector 64 electrically communicate with the plurality of testing modules 66 to create a first end of a testing circuit for the battery testing unit 50 when the modules 66 engage the battery unit.

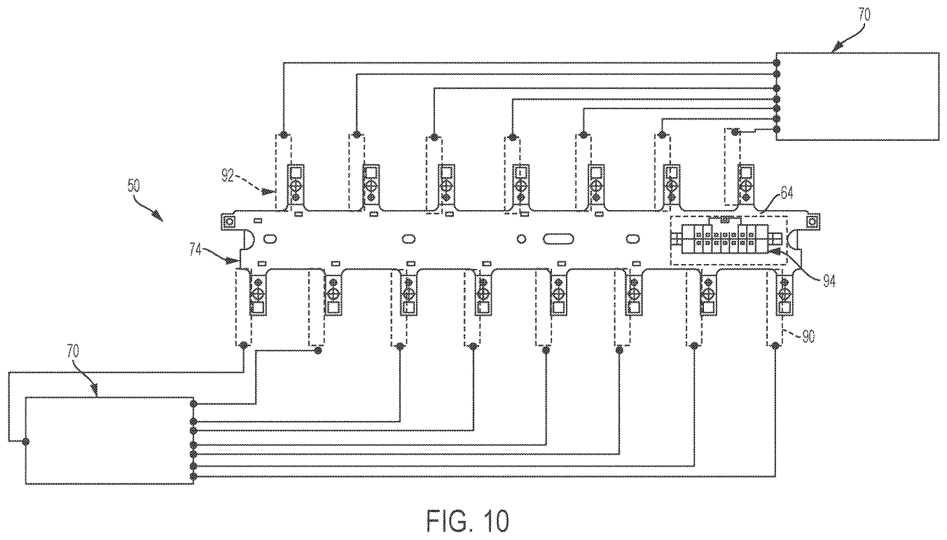

The plurality of testing modules 66 may be in communication with a controller 70 through the at least one external connector 64. Controller 70, as shown in FIG. 10, is configured to, at least in part, control the operation of the battery testing unit 50 and/or perform one or more determinations of electrical connection quality in the battery unit 60 consistent with embodiments disclosed herein. Among other things, the controller 70 may include one or more voltmeters and/or current sources configured to be used in connection with determining electrical connection quality consistent with embodiments disclosed herein.

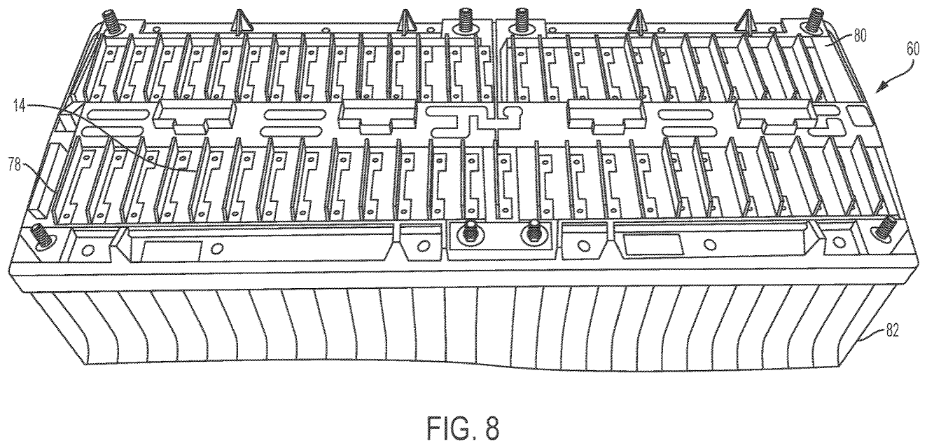

At least one pin or element 72 is provided on and extends from one or more of the plurality of modules 66. As illustrated in FIG. 5, the at least one element 72 extends downward from the lower surface 56 of the housing 52 and may be configured to engage a portion of the ICB 74 of the battery module as best shown in FIG. 10 and in FIG. 1 as interconnecting board 108 of battery module 101. The at least one element 72 is in electrical communication with the controller 70 through the at least one external connector 64 and may be configured to electrically contact opposing sides of tabs 20 during testing and/or measurement operations when the testing unit 50 is placed adjacent battery unit 60 as illustrated in FIG. 8. It is contemplated that an interface 76 may be provided in the housing 52 of the battery testing unit 50 that allows the at least one external connector 64 to communicate with the at least one element 72. Interface 76 may also be in electrical communication with the one or more contacts 90.

In one embodiment of the disclosure, the at least one element 72 of the battery testing unit 50 may be a spring loaded projection, pin or “pogo-pin” such that, when element 72 is pressed between the module 66 and ICB 74, points at each end of the element are in contact with and electrically connect the testing module 66 and ICB 74. It is contemplated that use of the spring loaded elements 72 may reduce the number of wiring connection points in the testing unit 50, thereby reducing complexity of maintenance of the testing unit 50. Further, use of spring loaded elements 72 may improve testing results of the battery testing unit 50 by reducing false test failures and potential damage to the tabs during testing.

Additionally, when the battery testing unit 50 is positioned on battery unit 60, the at least one element 72 engages a portion of the ICB 74, thereby closing element 72 so as to make electrical contact between the module 66 and ICB 74. Alternatively, the at least one element 72 engages a portion of a fastener or rivet that interconnects the battery cell sense line in the U-channel 68 and a trace line connected to the ICB 74 to evaluate the quality of the rivet or fastener connection. The interconnection of the module 66 and ICB 74 is represented by box 94. Controller 70 in communication with element 72 and contacts 90 may simultaneously evaluate voltage and resistance measurements.

A non-limiting exemplary embodiment of the battery unit 60 is illustrated in FIG. 8. Battery unit 60 may include one or more battery packs or sections 78, 80 and may include integrally formed fluid cooling passages 82 each extending along the length of the battery unit 60 and located on opposite lateral sides of the battery cells 14. The fluid cooling passages 82 of each battery section 78, 80 are connected to the corresponding passages of an adjacent battery section 78, 80 or to another portion of a cooling circuit by hoses and tubes.

Each battery pack or section 78, 80 may include multiple voltage temperature sub-modules (VTSM) stacked along a length of the battery section, each VTSM having a battery cell 14, replacement frame, jacket and foam. Each VTSM has a positive tab and a negative tab and the tabs of adjacent VTSMs are welded together. Preferably, the cells 14 contain the battery electrolyte, lithium ions, in the form of a gel.

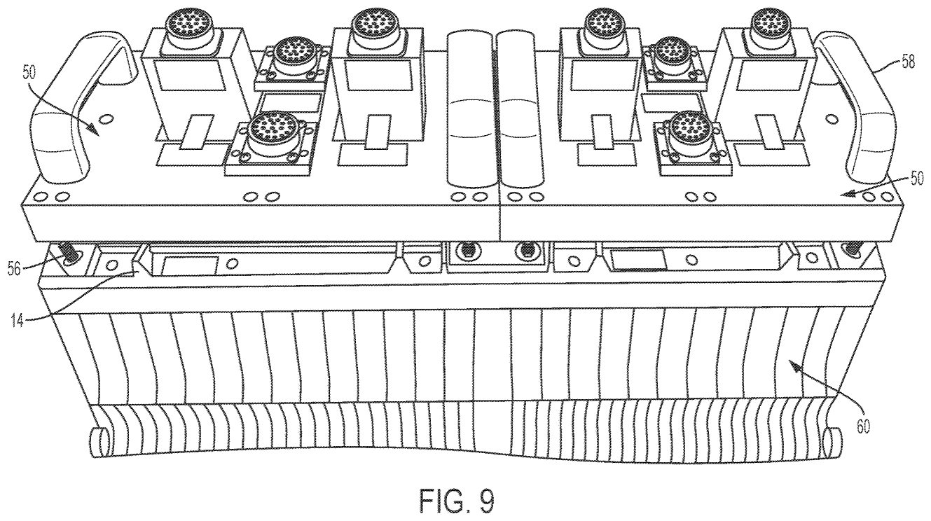

As is shown in FIG. 9, one or more battery testing units 50 are sized to cooperate with an upper portion of the battery unit 60. Battery testing units 50 cooperate with the battery cell sections with welded interconnecting members and battery cells received within the plurality of channels in the lower surface of the battery channel housing 52. The one or more handles 58 on the upper surface of the housing 52 are used to adjustably position the testing unit 50 in position on the battery unit 60 to ensure an appropriate connection to test the battery sections.

Referring now to FIGS. 6, 7 and 10, one or more contacts 90 are provided on at least one surface of the plurality of testing modules 66. In one embodiment of the disclosure, at least one contact 90 is provided adjacent one of the surfaces of the channel 68 formed between two of the plurality of testing modules 66. The at least one contact 90 is in electrical communication with the controller 70 through interface 76 disposed in the battery testing unit housing 52. The at least one contact 90 provides contact points for supplying an electrical current across the tabs for the interconnecting member and battery cells.

As shown in the sectional view in FIG. 7, the at least one contact 90 may be shaped to be biased against the tab to ensure electrical contact for testing purposes. The one or more contacts 90 electrically communicate with the battery tabs and/or associated interconnecting member of the battery module of the battery unit 60 to create a second end of a testing circuit for the battery testing unit 50 that cooperates with the first end of the testing circuit provided by the plurality of testing modules 66.

In further embodiments, the contacts 90 may be configured to provide contact points for measuring one or more voltages across the tabs for the interconnecting member and battery cells to electrically contact one or more sides of the tabs and/or the associated interconnecting member 12 as represented by boxes 92. Additionally, when the battery testing unit 50 is positioned on battery unit 60, the at least one element 72 engages a portion of the ICB 74, thereby closing element 72 so as to make electrical contact between the module 66 and ICB. The interconnection of the module 66 and ICB 74 is represented by box 94. Controller 70 is in communication with element 72 and contacts 90 may simultaneously evaluate voltage and resistance measurements.

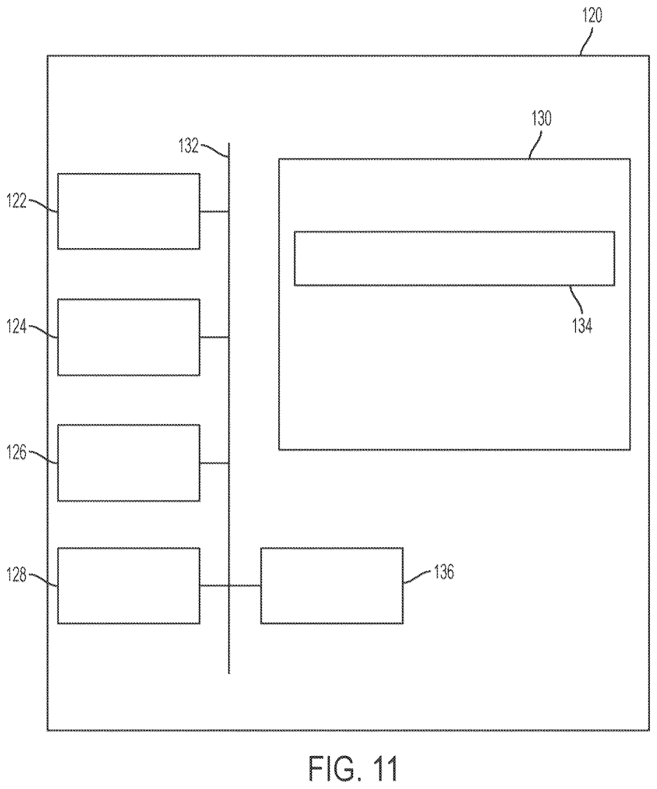

FIG. 11 illustrates an exemplary system 120 for implementing certain embodiments of the systems and methods disclosed herein. In certain embodiments, the computer system 120 may be a personal computer system, a server computer system, a testing control system, and/or other type of system for implementing the disclosed systems and methods. In further embodiments, the computer system 120 may be a portable electronic computer system or electronic device including, for example, a notebook computer, a smartphone, and/or a tablet computer.

As illustrated, the computer system 120 may include, among other things, one or more processors 122, random access memory (“RAM”) 124, a communications interface 126, a user interface 128, a measurement and/or testing interface 136 configured to supply one or more electrical currents and/or measure one or more voltages, and a non transitory computer-readable storage medium 130. The processor 122, RAM 124, communications interface 126, user interface 128, measurement and/or testing interface 136, and computer-readable storage medium 130 may be communicatively coupled to each other via a common data bus 132. In some embodiments, the various components of the computer system 120 may be implemented using hardware, software, firmware, and/or a combination thereof.

User interface 128 may include a number of devices allowing a user to interact with the computer system 120. For example, user interface 128 may be used to display an interactive interface to a user. The user interface 128 may be a separate interface system communicatively coupled with the computer system 120 or, alternatively, may be an integrated system such as a display interface for a laptop or other similar device. In certain embodiments, the user interface 128 may be produced on a touch screen display. The user interface 128 may also include a number of other input devices including, for example, keyboard, trackball, and/or pointer devices.

The communications interface 126 may be an interface capable of communicating with other computer systems, peripheral devices, and/or other equipment communicatively coupled to computer system 120. For example, the communications interface 126 may allow the computer system 120 to communicate with other computer systems (e.g., computer systems associated with external databases and/or the Internet), allowing for the transfer as well as reception of data from such systems. The communications interface 126 may include, among other things, a modem, a satellite data transmission system, an Ethernet card, and/or other device that enables the computer system 120 to connect to databases and networks, such as LANs, MANs, WANs and the Internet.

Processor 122 may include one or more general purpose processors, application specific processors, programmable microprocessors, microcontrollers, digital signal processors, FPGAs, other customizable or programmable processing devices, and/or other devices or arrangement of devices that are capable of implementing the systems and methods disclosed herein.

Processor 122 may be configured to execute computer-readable instructions stored on non-transitory computer-readable storage medium 130. Computer-readable storage medium 130 may store other data or information as desired. In some embodiments, the computer-readable instructions may include computer executable functional modules 134. For example, the computer-readable instructions may include one or more functional modules configured to implement the functionality of the systems and methods described above. Specific functional models that may be stored on computer-readable storage medium 130 may include a module configured to control a current source, a module configured to measure one or more voltages, a module configured to determine one or more measured resistances, a module configured to perform electrical connection quality determinations consistent with embodiments disclosed herein, and/or other module or modules configured to implement the systems and methods disclosed herein.

The system and methods described herein may be implemented independent of the programming language used to create the computer-readable instructions and/or an operating system operating on the computer system 120. For example, the computer-readable instructions may be written in a programming language, examples of which include, but are not limited to, C, C++, Visual C++, and/or Visual Basic, Java, Perl, or another programming language. Further, the computer-readable instructions and/or functional modules may be in the form of a collection of separate programs or modules, and/or a program module within a larger program or a portion of a program module. The processing of data by computer system 120 may be in response to user commands, results of previous processing, or a request made by another processing machine. It will be appreciated that computer system 120 may utilize an operating system including, for example, Unix, DOS, Android, Symbian, Windows, iOS, OSX, Linux, and/or the like.

FIGS. 1-11 illustrate and describe a testing system for a battery, such as a system for evaluating battery connection quality in a battery assembly. Embodiments herein are not limited to such testing. For example, embodiments herein may include or be provided for use with systems for evaluating weld junctions, measuring various cell voltages, evaluating structural strength; evaluating the integrity of structural adhesive material (SAM), evaluating the integrity of thermal interface material (TIM), or evaluating other characteristics of a battery.

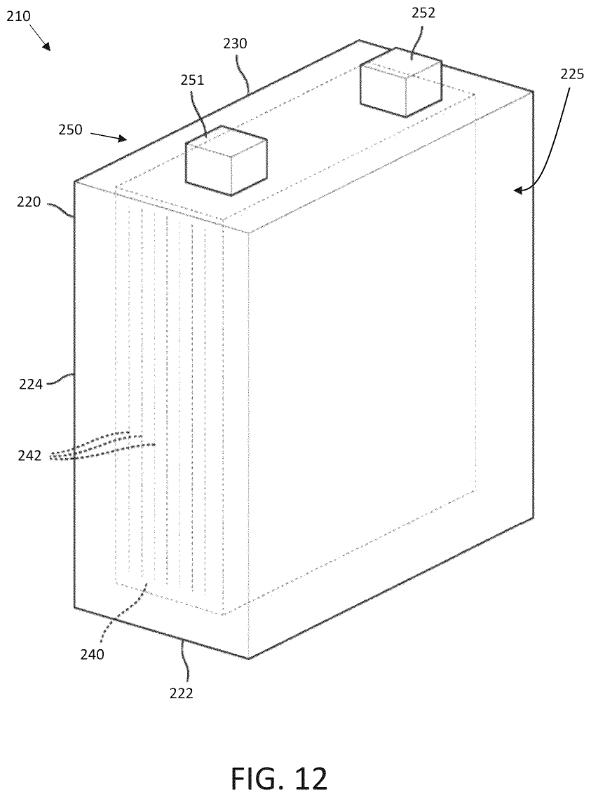

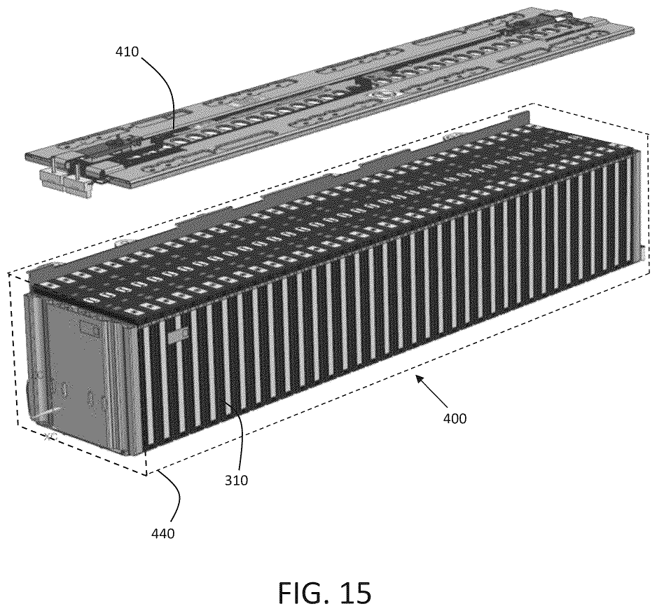

FIGS. 12-16 describe embodiments in which equipment, such as described above, is set up for use with a production battery module by first using a surrogate battery module.

Specifically, further embodiments herein provide a prudent low-cost alternative to using production battery cells in module manufacturing, particularly when equipment is being assembled, or being set up for use in testing or evaluating the production battery cells. Battery assembly processes may include robotic transfer, conveyors, and any other type of assembly, joining, welding, and stacking equipment. As used herein, equipment for processing the battery includes equipment for assembling, transferring, conveying, joining, welding, stacking, setting up, testing, and/or evaluating the battery.

Rather than use the production battery cell during such processing, such as assembly, set up, modification or calibration; a surrogate battery module is designed and built to mimic the size, weight, center-of-gravity, surface characteristics, and internal electrical characteristics of the production battery cells so that testing equipment may be set up, modified, calibrated, etc., without use of the production battery cells.

In certain embodiments, such as for testing electrical connections, the surrogate battery module includes a low capacity power source. For example, the low capacity power source may have a capacity of less than fifty Watt hours, such as less than twenty Watt hours, for example less than ten Watt hours. In certain embodiments, a low capacity off-the-shelf battery cell, like an AA battery having a capacity of two-thousand milliamp hours, may be installed in the surrogate battery module. On the other hand, a production battery module may have an energy capacity of over two-hundred Watt hours, such as over three-hundred Watt hours. For example, certain lithium-ion batteries have a capacity of three-hundred-and-seventy Watt hours.

In embodiments in which only non-electrical testing is performed, the surrogate battery module itself may not include any power source, i.e., battery cell including an anode and cathode. Thus, such embodiments are free of lithium-ion sources or any other battery chemistry, i.e., the surrogate battery module is free of battery chemicals. Therefore, such embodiments of the surrogate battery module eliminate any chance of a chemical event while being manipulated by testing equipment and render moot any precaution necessitated when working with possible sources of chemical events.

In certain embodiments, the use of the surrogate battery module may be limited to tryout, debug and initial set-up of testing equipment. Therefore the surrogate battery module may be dedicated to improving the manufacturing processes as a quality gauge.

It is further noted that production battery cells are expensive. In certain embodiments, testing to prove out a manufacturing system may be based on use of 20,000 to 30,000 battery cells. Therefore, use of production battery cells would cost tens of millions of dollars. On the other hand, the cost of using 20,000 to 30,000 surrogate battery modules during prove out may be limited to less than one thousand dollars.

Also, testing of production battery cells present handling concerns when used as production intent components. For example, early in process development when processes are not yet tune, there is a risk of breaching battery modules or shorting battery modules. Use of inert surrogate battery modules provides the ability to make process equipment adjustments, and may be used anywhere in the manufacturing process, from assembly, to welding, to testing and measuring voltages for ensuring quality in the process.

Further, in some cases, such as when a new battery product has not yet undergone 0the initial production run, production battery cells are not available early enough to support equipment set up and acceptance.

Therefore, there exists within manufacturing operations, a need for a battery cell or module that facilitates handling, and equipment set-up, debugging or postproduction changes.

Certain embodiments involve manufacturing battery module and pack-main-line run-off/at rate/at supplier, wet-out teardown production processes checks for structural adhesive material (SAM) and thermal interface material (TIM).

Embodiments herein provide a surrogate cell or module that acts like a production cell or module in the cell process, module and pack assembly processes. In certain embodiments, the production cell or module is a battery enclosed in a can. To mimic production handling, the surrogate unit is provided with the same mass, same center of gravity, and same surface finish as the production unit that will eventually undergo evaluation or testing. To emulate the surface finish and materials of the production unit, a housing for the surrogate unit is formed as a plastic cast housing having the same shape and size, i.e., form and fit, of the production can cell. To match the surface properties of the production can cell, embodiments herein select a grain of the mold used to cast the plastic housing so that the plastic housing grain matches the surface finish/coefficient of friction of the PET film on the production can cell.

To match the mass and center-of-gravity of the production can cell, the surrogate unit is modeled with the desired housing and internal components and with a ballast mass. The ballast mass may be provided as a single piece or as multiple pieces. modeling may also include evaluating the combination of the housing and the ballast mass to determine stiffness (short side and long side) to match the bidirectional stiffness of the production unit in the surrogate unit. The mass, center-of-gravity, and stiffness may be modified through modifying the size, shape, and density of the ballast mass (including material selection) and/or the internal molded shape and size and material selection of the housing. For example, high density particulate, such as steel shot, could be added to increase mass and modify the center-of-gravity. Stiffness may be modified by use of a composite of high-density particulate/lumped mass and RTV. These characteristics may be of particular importance when evaluating production stacking/compression.

When evaluating production cell welding quality, the surrogate may be modeled and formed to match the fit and form of production cell electrodes (anode/cathode). Further, the surrogate may utilize replaceable and re-usable electrode pads to facilitate multiple uses (past one-time use).

During set up for testing, a minimal power battery cell may be provided as the surrogate to provide test source at cell voltage. Set up would further include connecting the voltage source via fused protection to the anode electrode and the cathode electrode. In embodiments, the surrogate battery unit is provided with a same internal resistance as the production unit.

In certain embodiments, the surrogate battery nodule is provided with a programmable or variable voltage output with a programable LED barcode screen used to validate OCV test equipment.

Embodiments provide for use as an error proofing challenge part for OCV and electrical test equipment.

For quality assurance, tracking and error proofing, the surrogate cell may be provided with a cell label and/or barcode with embodied information including part number, date, voltage and other pertinent quality data.

In certain embodiments, the surrogate unit housing is formed from two common or same halves.

In certain embodiments, the surrogate unit has a same mass as the production unit for which the testing equipment is being set up.

In certain embodiments, the surrogate unit housing has a surface finish and static friction equal to plastic film (super fine grain/high polish mold).

In certain embodiments, the surrogate unit housing is insert molded or surface treated to provide aluminum structure attachment windows (locations on “thin” side of cell).

In certain embodiments, the surrogate unit mass is formed from the housing, internal electrical components, fasteners, and the additional ballast mass to obtain the same mass as the production unit.

In certain embodiments, the ballast mass is made of lumped mass (for example, a steel plate) or a mixture of adhesive and dense particulate (for example, steel shot).

In certain embodiments, the bidirectional stiffness (force vs displacement) of the production unit is matched by the surrogate unit by modeling the structure and ballast to obtain same performance characteristics.

In certain embodiments, the surrogate unit includes a designed closed shut feature limiting displacement at a prescribed force. For example, the internal ribs of the surrogate unit may provide a positive stop to a compressive force on the surrogate unit. In certain embodiments, the internal ribs are designed and formed to emulate the stiffness of the production battery cell.

In certain embodiments, the surrogate unit housing is re-usable for welding, by providing a disposable and detachable anode electrode and cathode electrode.

In certain embodiments, the surrogate unit is provided with an internal voltage source of low capacity providing potential to the anode and cathode electrode.

In certain embodiments, the surrogate unit is provided with an internal voltage source with characterized and matched resistance to the production cell, i.e., a same internal resistance.

In certain embodiments, the surrogate unit is provided with fused protection of voltage source at ⅛ A low current.

In certain embodiments, the surrogate unit is provided with a bar code label to embody key quality (part number, date, Open Circuit Voltage, etc.).

In certain embodiments, the surrogate unit is provided with a programable or editable barcode label to part number, date, Open Circuit Voltage, etc., such as when used for an Open Circuit Voltage test. Further embodiments support remote PC connectivity to enable the programable voltage output and barcode label information.

In certain embodiments, the surrogate unit is provided with a display, such as an LED screen, to display output voltage and/or to display the barcode label information

In certain embodiments, the surrogate unit is provided with internal circuitry to enable an adjustable voltage output that may be used to calibrate and validate assembly process test equipment.

In summary, embodiments herein provide a low cost replacement unit that matches/emulates production battery cell performance, with exception to high energy electrical performance, i.e., the replacement unit purposefully lacks a high capacity power supply. Embodiments herein provide reduce complications during first time use of testing or evaluation equipment when setting up, debugging, calibration, and trying change of risk in module manufacturing processes.

As indicated above, embodiments herein may be provided for use with a product battery module or cell 210 as shown in FIG. 12. The battery cell 210 may be a lithium-ion battery cell or a battery cell of a different chemistry.

FIG. 12 illustrates a product prismatic battery cell 210; however, embodiments herein are not limited to use with prismatic battery cells. For example, embodiments herein may be used with blade, pouch, or cylindrical cells.

The battery cell 210 is illustrated as including an outer case or enclosure 220 that surrounds and defines an internal space 225 within the enclosure 220. An exemplary outer enclosure 220 may be conductive. For example, the outer enclosure 220 may be metallic. In certain embodiments, the enclosure 220 is aluminum. The illustrated outer enclosure 220 is a rectangular polyhedron and includes relatively short side opposite faces 222 and relatively long side opposite faces 224.

As shown, the outer enclosure 220 may be formed with an open end, which is covered or closed by a cap 230. In certain embodiments, the cap 230 may be part of the enclosure 220. In certain embodiments, the cap 230 is conductive. For example, the cap 230 may be metallic, such as aluminum or aluminum alloy.

As shown, the battery cell 210 may include tabs or terminals 250, including a first tab or terminal 251, and an optional second tab or terminal 252. Each terminal 251, 252 may be in electrical connection with the battery cell components within the outer enclosure 220. In certain embodiments, each terminal 251, 252 is insulated from the cap 230.

In certain embodiments, the battery cell 210 includes an electrode assembly 240. As shown, the electrode assembly 240 is illustrated with dashed lines, indicating the electrode assembly 240 as a component of the battery cell 210 that is internal to the hard outer enclosure 220, i.e., located within the internal space 225. The electrode assembly 240 is illustrated with a plurality of electrode pair layers 242 arranged such that planar surfaces of the electrode pair layers 242 are perpendicular to the short faces 222. The electrode assembly 240 may be referred to as a stack 240 of electrode layers 242.

As described above, when setting up or other modifying or maneuvering testing or evaluation equipment, it may not be possible to use the product battery cell 210 or it may be desirable to use a surrogate unit.

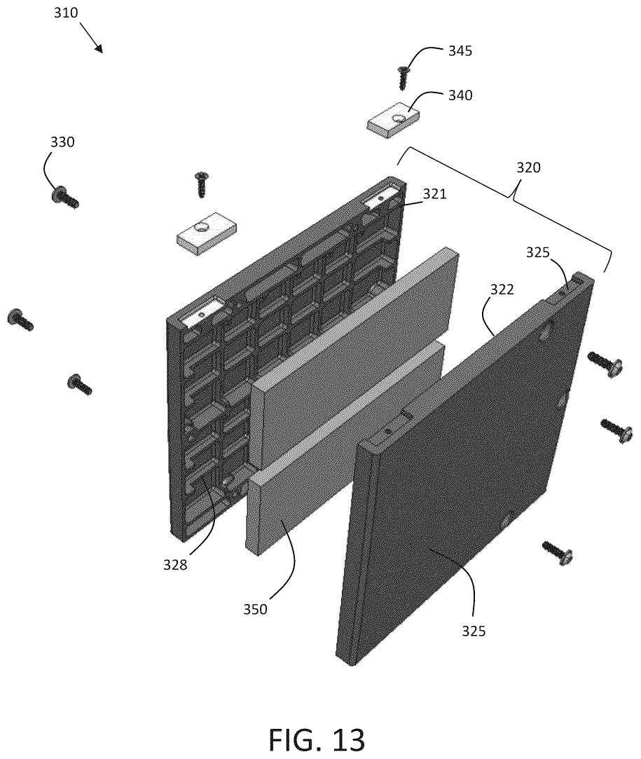

FIG. 13 is an exploded view of a surrogate unit 310, illustrating internal and external components. As shown, the surrogate unit 310 includes a housing 320. The housing 320 is formed from two parts 321 and 322. In certain embodiments, the two parts 321 and 322 are halves of the housing 320. In certain embodiments, the two parts are the same, and are connectable to one another. As shown, fasteners 330 are provided to secure the two parts 321 and 322 together.

The two parts 321 and 322 including internal ribs 328. The internal ribs 328 are designed with a closed shut feature limiting displacement at a prescribed force. For example, the internal ribs 328 provide a positive stop to a compressive force on the surrogate unit 310. In certain embodiments, the internal ribs 328 are designed and formed to emulate the stiffness of the production battery cell. For example, the production battery cell may have a bulge, and the internal ribs 328 are designed to emulate the bulge due to the closed shut feature.

The parts 321 and 322 are, and thus the housing 320 is, formed with an external surface 325. Further, recesses 326 are formed in the external surface, such as for receiving aluminum attachment contacts 340. As further shown, fasteners 345 are provided to fasten the attachment contacts 340 to the housing 320.

FIG. 13 also illustrates ballast material 350. In FIG. 13, the ballast material 350 is provided as two separate pieces, though any suitable form may be used.

The surrogate unit 310 may further include electronic components such as a voltage source, anode electrode, cathode electrode, and electrical connections, such as internal connections and connections to the attachment contacts 340, which are not illustrated in FIG. 13.

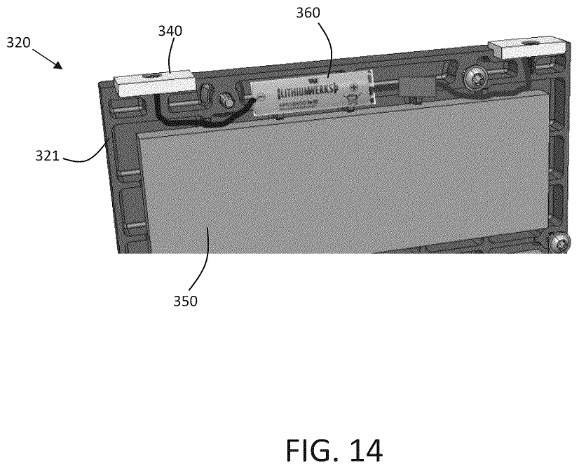

Referring now to FIG. 14, an internal view of one part 321 of the housing 320 is illustrated. An electrical component 360 is located in the housing 320 and is electrically connected to the attachment contacts 340. The electrical component 360 may include a voltage source, an anode electrode, and a cathode electrode. For example, the electrical component 360 may be an off-the-shelf battery cell having a low energy capacity.

As noted above, the surrogate unit 310 is designed to mimic the production unit 210 by having the same shape, same size, same dimensions, same mass, same center-of-gravity, same bidirectional stiffness, same surface characteristics, and some same electrical properties, i.e., same low voltage electrical properties.

In certain embodiments, a plurality of stacked surrogate units 310 are tested at a same time. For example, FIG. 14 illustrates a stack 400 of surrogate units 310. As shown, the surrogate units 310 are stacked and may be electrically connected to circuitry 410. For example, the circuitry may be a printed circuit board.

The stack 400 of surrogate units 310 is received in an external housing 400. Specifically, the surrogate units 310 may be strapped together under pressure and then the outer housing 440 may be assembled around the surrogate units 310. Further, the electrical components 360 of the surrogate units 310 and the circuitry 410 are electrically interconnected.

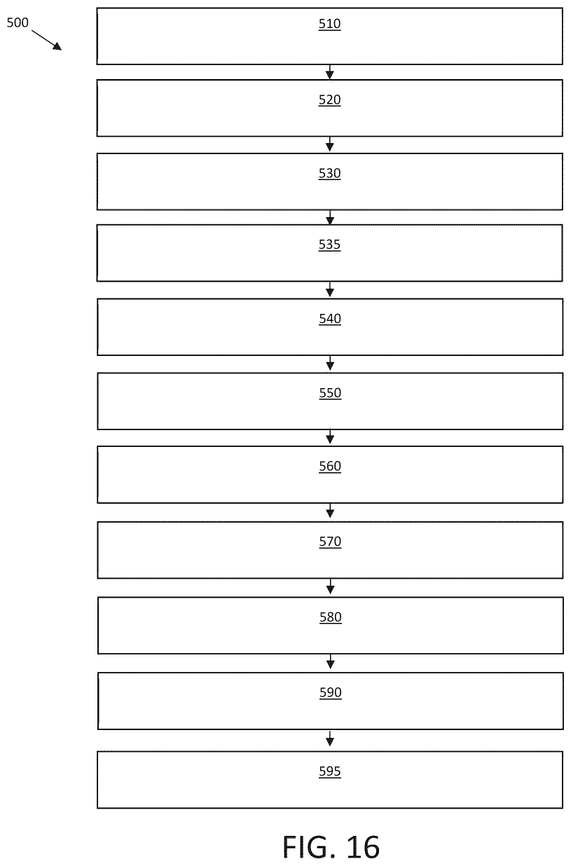

FIG. 16 is a flow chart illustrating a method 500 for testing a battery production unit 210.

Method 500 may include, at 510, determining a product exterior surface finish, product dimensions, product mass, and product center-of-gravity of the battery.

Method 500 may further include, at 510, determining a product resistance of the battery.

Method 500 may further include, at 510, determining a product directionally stiffness of the battery.

Method 500 may continue, at 520, with identifying a thermoplastic material and a surface grain for forming a housing having an exterior surface finish that is the same as the product exterior surface finish.

Method 500 may continue, at 530, with modeling, with the processor, a surrogate battery including the housing and a ballast mass received within the housing, to provide the surrogate battery with a surrogate mass the same as the product mass and a surrogate center-of-gravity the same as the product center-of-gravity.

Method 500 may include, at 530, modeling, with the processor, an internal voltage source received within the housing, wherein the internal voltage source has a resistance that is the same as the product resistance.

Method 500 may include, at 530, modeling, with the processor, the surrogate battery including the housing, the ballast mass, the internal voltage source, an anode electrode and a cathode electrode received within the housing.

Method 500 may include, at 530, modeling, with the processor, the surrogate battery including the housing, the ballast mass, the internal voltage source, an anode electrode, and a cathode electrode received within the housing and attachment contacts.

Method 500 may include, at 530, modeling, with the processor, the surrogate battery to provide the surrogate battery with a bidirectional stiffness the same as the product bidirectional stiffness.

Method 500 may include, at 530, modeling, with the processor, the surrogate battery including the housing, the ballast mass, the internal voltage source, an anode electrode, and a cathode electrode received within the housing and attachment contacts.

Method 500 may include, at 530, modeling, with the processor, the surrogate battery including the housing, the attachment contacts, the internal voltage source, the ballast mass, and the fasteners.

Method 500 may continue, at 535, with preparing a mold for the housing, wherein forming the housing from the thermoplastic material and with the surface grain comprises molding the housing with the mold.

Method 500 may continue, at 540, with forming the housing from the thermoplastic material and with the surface grain.

Method 500 may include, at 540, forming a first part and a second part of the housing.

Method 500 may continue, at 550, with forming the surrogate battery by positioning the ballast mass within the housing.

Method 500 may further include, at 550, positioning the internal voltage source within the housing.

Method 500 may further include, at 550, positioning the anode electrode and the cathode electrode within the housing.

Method 500 may further include, at 550, positioning the ballast mass, the internal voltage source, the anode electrode and the cathode electrode within the housing and mounting the attachment contacts onto the housing to form the surrogate battery.

Method 500 may further include, at 550, positioning the ballast mass, the internal voltage source, the anode electrode and the cathode electrode within the housing and mounting the attachment contacts onto the housing to form the surrogate battery, wherein the attachment contacts are fastened to the housing and the first part is secured to the second part with fasteners.

Method 500 may further include, at 550, securing the first part of the housing to the second part of the housing after locating the internal voltage source and the ballast mass between the first part and the second part.

Method 500 may continue, at 560, with setting up equipment for processing the battery, such as for assembling or evaluating the battery, by engaging the equipment with the surrogate battery. As described above, the surrogate battery may be provided in the form of a stack of surrogate batteries located in an outer housing. Method 500 may further include, at 560, performing electrical, structural, or other desired testing to determine testing procedures and parameters.

After completing set up, modification, debugging, or other testing of the equipment, method 500 may continue, at 570, with removing the surrogate battery from the equipment.

Method 500 may continue, at 580, with engaging the battery with the equipment.

Method 500 may continue, at 590, with performing testing on the battery.

Method 500 may continue, at 595, with removing the electrical component (low capacity battery cell) from the housing of the surrogate unit; and replacing the electrical component (low capacity battery cell) with a second electrical component (low capacity battery cell) having properties that match a different production battery, before repeating the modeling, forming, and setting up operations using the surrogate unit comprising the housing and the second electrical component selected for a second battery.

The foregoing specification has been described with reference to various embodiments. Various operational steps, as well as components for carrying out operational steps, may be implemented in alternate ways depending upon the particular application or in consideration of a number of cost functions associated with the operation of the system. For example, one or more of the steps may be deleted, modified, or combined with other steps. Further, this disclosure is to be regarded in an illustrative rather than a restrictive sense, and the modifications are intended to be included within the scope thereof.

As used herein, the terms “comprises” and “includes,” and other variations thereof, are intended to cover a non-exclusive inclusion, such that a process, a method, an article, or an apparatus that comprises a list of elements includes those elements and may include other elements not expressly listed or inherent to such process, method, system, article, or apparatus. Also, as used herein, the terms “coupled,” “coupling,” and other variations thereof are intended to cover a physical connection, an electrical connection, a magnetic connection, an optical connection, a communicative connection, a functional connection, and/or other connection.

The detailed description and the drawings or figures are supportive and descriptive of the disclosure, but the scope of the disclosure is defined solely by the claims. While some of the best modes and other embodiments for carrying out the claimed disclosure have been described in detail, various alternative designs and embodiments exist for practicing the disclosure defined in the appended claims. Furthermore, the embodiments shown in the drawings or the characteristics of various embodiments mentioned in the present description are not necessarily to be understood as embodiments independent of each other. Rather, it is possible that each of the characteristics described in one of the examples of an embodiment may be combined with one or a plurality of other desired characteristics from other embodiments, resulting in other embodiments not described in words or by reference to the drawings. Accordingly, such other embodiments fall within the framework of the scope of the appended claims.

What is claimed is:

1. A method for preparing for processing of a production battery, the method comprising:
determining a product exterior surface finish, product dimensions, product mass, and product center-of-gravity of the production battery;
identifying a thermoplastic material and a surface grain for forming a housing having an exterior surface finish that is the same as the product exterior surface finish;
modeling, with a processor, a surrogate battery including the housing and a ballast mass received within the housing, to provide the surrogate battery with a surrogate mass the same as the product mass and a surrogate center-of-gravity the same as the product center-of-gravity;
forming the housing from the thermoplastic material and with the surface grain;
forming the surrogate battery by positioning the ballast mass within the housing; and
setting up equipment for processing the production battery by engaging the equipment with the surrogate battery.

2. The method of claim 1, further comprising determining a product resistance of the production battery, wherein modeling the surrogate battery comprises modeling the surrogate battery including the housing, the ballast mass, and an internal voltage source received within the housing, wherein the internal voltage source has a resistance that is the same as the product resistance, and wherein forming the surrogate battery comprises positioning the ballast mass and the internal voltage source within the housing.

3. The method of claim 2, wherein modeling the surrogate battery comprises modeling the surrogate battery including the housing, the ballast mass, the internal voltage source, an anode electrode and a cathode electrode received within the housing, wherein forming the surrogate battery comprises positioning the ballast mass, the internal voltage source, the anode electrode and the cathode electrode within the housing.

4. The method of claim 3, wherein the anode electrode is a first anode electrode and the cathode electrode is a first cathode electrode, and wherein the method further comprises:
removing the first anode electrode and the first cathode electrode from the housing; and
repeating the modeling, forming, and setting up operations using the housing with a second anode electrode and a second cathode electrode selected for a second battery.

5. The method of claim 2, wherein modeling the surrogate battery comprises modeling the surrogate battery including the housing, the ballast mass, the internal voltage source, an anode electrode, and a cathode electrode received within the housing and attachment contacts, wherein forming the surrogate battery comprises positioning the ballast mass, the internal voltage source, the anode electrode and the cathode electrode within the housing and mounting the attachment contacts onto the housing to form the surrogate battery.

6. The method of claim 1, further comprising preparing a mold for the housing, wherein forming the housing from the thermoplastic material and with the surface grain comprises molding the housing with the mold.

7. The method of claim 2, wherein forming the housing from the thermoplastic material and with the surface grain comprises forming a first part and a second part of the housing, and wherein the method further comprises securing the first part to the second part after locating the internal voltage source and the ballast mass between the first part and the second part.

8. The method of claim 7, wherein modeling the surrogate battery comprises modeling the surrogate battery including the housing, the ballast mass, the internal voltage source, an anode electrode, and a cathode electrode received within the housing and attachment contacts, wherein forming the surrogate battery comprises positioning the ballast mass, the internal voltage source, the anode electrode and the cathode electrode within the housing and mounting the attachment contacts onto the housing to form the surrogate battery, wherein the attachment contacts are fastened to the housing and the first part is secured to the second part with fasteners, and wherein modeling the surrogate battery comprises modeling the surrogate battery including the housing, the attachment contacts, the internal voltage source, the ballast mass, and the fasteners.

9. The method of claim 1, further comprising determining a product bidirectional stiffness of the production battery, wherein modeling the surrogate battery includes modeling the surrogate battery to provide the surrogate battery with a bidirectional stiffness the same as the product bidirectional stiffness.

10. A method for testing a production battery, the method comprising:
determining a product exterior surface finish, product dimensions, product mass, and product center-of-gravity of the production battery;
identifying a thermoplastic material and a surface grain for forming a housing having an exterior surface finish that is the same as the product exterior surface finish;
modeling, with a processor, a surrogate battery including the housing and a ballast mass received within the housing, to provide the surrogate battery with a surrogate mass the same as the product mass and a surrogate center-of-gravity the same as the product center-of-gravity;
forming the housing from the thermoplastic material and with the surface grain;
forming the surrogate battery by positioning the ballast mass within the housing;
setting up equipment for processing the production battery by engaging the equipment with the surrogate battery;
removing the surrogate battery from the equipment;
engaging the production battery with the equipment; and
performing testing on the production battery.

11. The method of claim 10, further comprising determining a product resistance of the production battery, wherein modeling the surrogate battery comprises modeling the surrogate battery including the housing, the ballast mass, and an internal voltage source received within the housing, wherein the internal voltage source has a resistance that is the same as the product resistance, and wherein forming the surrogate battery comprises positioning the ballast mass and the internal voltage source within the housing.

12. The method of claim 11, wherein modeling the surrogate battery comprises modeling the surrogate battery including the housing, the ballast mass, the internal voltage source, an anode electrode and a cathode electrode received within the housing, wherein forming the surrogate battery comprises positioning the ballast mass, the internal voltage source, the anode electrode and the cathode electrode within the housing.

13. The method of claim 12, wherein the anode electrode is a first anode electrode and the cathode electrode is a first cathode electrode, and wherein the method further comprises:
removing the first anode electrode and the first cathode electrode from the housing; and
repeating the modeling, forming, and setting up operations using the housing with a second anode electrode and a second cathode electrode selected for a second battery.

14. The method of claim 11, wherein modeling the surrogate battery comprises modeling the surrogate battery including the housing, the ballast mass, the internal voltage source, an anode electrode, and a cathode electrode received within the housing and attachment contacts, wherein forming the surrogate battery comprises positioning the ballast mass, the internal voltage source, the anode electrode and the cathode electrode within the housing and mounting the attachment contacts onto the housing to form the surrogate battery.

15. The method of claim 10, further comprising preparing a mold for the housing, wherein forming the housing from the thermoplastic material and with the surface grain comprises molding the housing with the mold.

16. The method of claim 11, wherein forming the housing from the thermoplastic material and with the surface grain comprises forming a first part and a second part of the housing, and wherein the method further comprises securing the first part to the second part after locating the internal voltage source and the ballast mass between the first part and the second part.

17. The method of claim 16, wherein modeling the surrogate battery comprises modeling the surrogate battery including the housing, the ballast mass, the internal voltage source, an anode electrode, and a cathode electrode received within the housing and attachment contacts, wherein forming the surrogate battery comprises positioning the ballast mass, the internal voltage source, the anode electrode and the cathode electrode within the housing and mounting the attachment contacts onto the housing to form the surrogate battery, wherein the attachment contacts are fastened to the housing and the first part is secured to the second part with fasteners, and wherein modeling the surrogate battery comprises modeling the surrogate battery including the housing, the attachment contacts, the internal voltage source, the ballast mass, and the fasteners.

18. The method of claim 10, wherein performing testing on the production battery comprises checking structural adhesive material (SAM).

19. The method of claim 10, wherein performing testing on the production battery comprises checking thermal interface material (TIM).

20. A system for processing a production battery, the system comprising:
a processor configured to:
identify a material and a surface grain for forming a housing having an exterior surface finish that is the same as a product exterior surface finish of the production battery; and
model a surrogate battery including the housing and a ballast mass received within the housing, to provide the surrogate battery with a surrogate mass the same as a product mass of the production battery and a surrogate center-of-gravity the same as a product center-of-gravity of the production battery;
a mold for forming the housing;
the ballast mass; and
equipment for processing the production battery, wherein the equipment is configured to engage the surrogate battery during a set up operation.
